(19) United States
(12) Patent Application Publication
(10) Pub. No.: US 2006/0006431 A1
(43) Pub. Date: Jan. 12, 2006

(54) Metal oxide semiconductor (MOS) varactor

(75) Inventors: Yuh-Sheng Jean, Dapi Township (TW); Ta-Hsun Yeh, Hsin-Chu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Realtek Semiconductor Corp.

(21) Appl. No.: 11/174,743

(22) Filed: Jul. 5, 2005

(30) Foreign Application Priority Data
Jul. 6, 2004 (TW) 93120175

(51) Int. Cl. H01L 29/76; H01L 21/336

(52) U.S. Cl. 257/288; 438/197; 257/312; 257/368; 438/379

(57) ABSTRACT

A metal oxide semiconductor (MOS) varactor includes a first terminal and a second terminal, and the MOS varactor comprises a substrate; a deep well, formed on the substrate; and a first MOS device, formed on the deep well; wherein a gate of the first MOS device is coupled to the first terminal, and a source and a drain of the first MOS device are coupled to the second terminal.

This application claims the benefit of Taiwan application Serial No. 093120175, filed Jul. 6, 2004, the subject matter of which is incorporated herein by reference.

### BACKGROUND OF THE INVENTION

1. Field of the Invention

The invention relates in general to a varactor, and more particularly to a metal oxide semiconductor (MOS) varactor.

2. Description of the Related Art

The MOS varactor, an essential device in the RF IC design field, is widely applied to voltage controlled oscillator (VCO) circuit and tunable filter circuit. The tuning range is the capacitance range a varactor can provides and is defined by Cmax/Cmin. Ordinary speaking, it is preferred that the varactor has a large tuning range, and the linearity refers to whether the varactor is easily utilized.

FIG. 1 is an ordinary MOS varactor structure and FIG. 2 is the capacitance/voltage (CV) curve of the MOS varactor. In the structure of the MOS varactor of FIG. 1, the tuning range is determined by the thickness of the oxide layer and the doping concentration of the N well in the MOS. Therefore, the tuning range of the MOS varactor structure can be only increased by reducing the oxide layer thickness or well concentration, for example, as disclosed in Chapter 7, “Physics of semiconductor devices” second edition, 1981, S. M. Sze. However, the oxide layer thickness has physical limitation and every semiconductor process has constant oxide layer thickness, which cannot be changed casually, and reducing well concentration means changing process.

There are prior arts as disclosed in U.S. Pat. No. 6,674,116, entitled “variable capacitor using MOS gated diode with multiple segments to limit dc current”, U.S. Pat. No. 6,400,001, entitled “Varactor, in particular for radio-frequency transceivers”, U.S. Pat. No. 6,407,412, entitled “MOS varactor structure with engineered voltage control range”, and U.S. Pat. No. 6,653,716, entitled “Varactor and method of forming a varactor with an increased linear tuning range”.

### SUMMARY OF THE INVENTION

It is therefore an object of the invention to provide a varactor, which can provide a relatively larger tuning range without change semiconductor process.

It is therefore an object of the invention to provide a method of manufacturing a MOS varactor having a deep N well to provide a large tuning range by the available semiconductor process.

According to the claimed invention, a MOS varactor is disclosed. The MOS varactor having a first terminal and a second terminal, includes: a substrate; a deep well, formed on the substrate; and a MOS device, formed on the deep well, wherein a gate of the MOS device is coupled to the first terminal, and a source and a drain of the MOS devices are coupled to the second terminal.

According to the claimed invention, a method of manufacturing a metal oxide semiconductor (MOS) varactor which has a first terminal and a second terminal is disclosed. The method comprises: forming a deep well on a substrate; forming a first MOS device on the deep well; coupling a gate of the first MOS device to the first terminal; and coupling a source and a drain of the first MOS device to the second terminal.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a conventional MOS varactor structure.

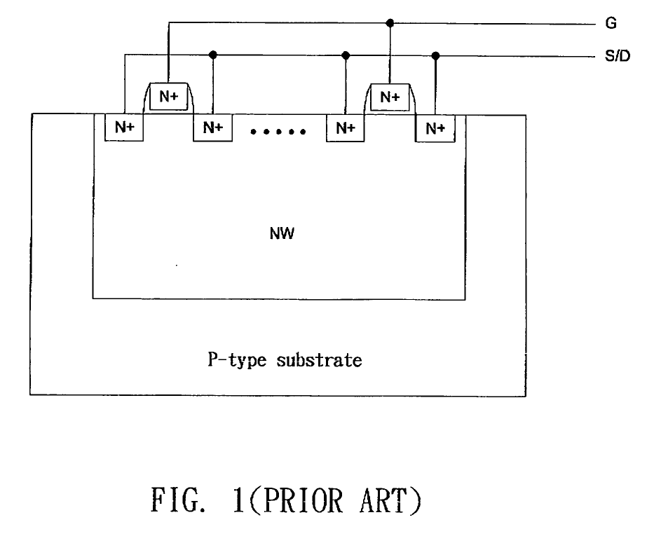

FIG. 2 (Prior Art) is the capacitance/voltage (CV) curve of the conventional MOS varactor.

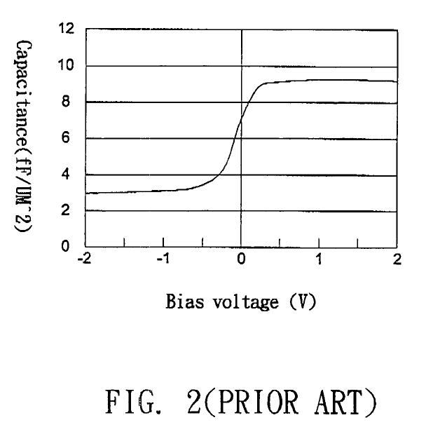

FIG. 3 is a MOS varactor structure according to the embodiment of the invention.

FIG. 4 is a CV curve of the MOS varactor according to the embodiment of the invention.

FIG. 5 is a MOS varactor structure according to another embodiment of the invention.

### DETAILED DESCRIPTION OF THE INVENTION

As mentioned in the prior art, the tuning range of the MOS varactor can be only increased by reducing the oxide layer thickness or the well concentration. However, the oxide layer thickness has physical limitation and every semiconductor process has constant oxide layer thickness, which cannot be changed casually, and reducing well concentration means changing process. Therefore, the invention provides a structure of a MOS varactor, which can be manufactured by the available process, for example, the TSMC 0.18 um RF process.

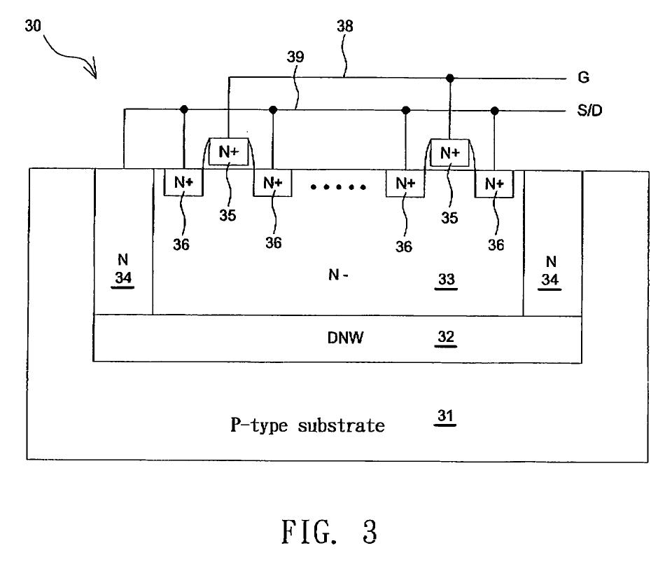

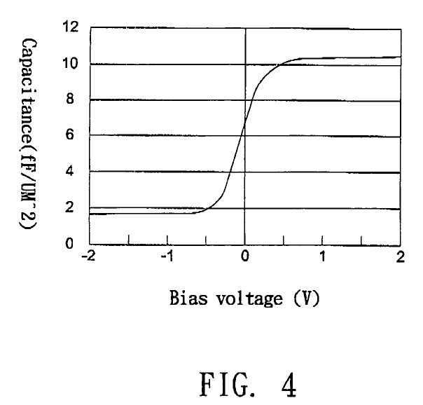

FIG. 3 is a MOS varactor structure of the invention according to the embodiment of the invention while FIG. 4 is a CV curve of the MOS varactor operated at a low frequency according to the embodiment of the invention. As shown in FIG. 3, the MOS varactor 30 of the invention, formed on a P-type substrate 31, includes a deep N well 32, a N-type low doping region 33, a N well 34, a number of first N-type high doping region 35, and a number of second N-type high doping region 36. The deep N well 32 is formed on the P-type substrate 31 while the N-type low doping region 33 is formed on the deep N well 32. The N well 34 is formed on the deep N well 32 and surrounding the N-type low doping region 33, while the first N-type high doping region 35 and the second N-type high doping region 36 are formed on the N-type low doping region 33. Moreover, a metal line 38 is connected to the first N-type high doping region 35 as a first output terminal G while a metal line 39 is connected to the second N-type high doping region 36 as a second output terminal S/D. In one embodiment, the N-well 34 can be a N-type high doping region. In another embodiment, the N-type low doping region 33 is formed by the neutralization of ions of the P-type substrate 31 and the deep N well 32 at the shallow layer. In the meanwhile, the metal line 39 is connected to the N well 34 so as to reduce the equivalent resistance and increase the Q value. In another embodiment, the MOS varactor can have a very low doping concentration to provide a relatively higher tuning range by the standard process of forming a MOSFET device without ion-implanting the N-type doping region 33 and the N channel and placing the device into the deep N well.

Referring to FIG. 3, as mentioned above, the first N-type high doping region 35 and the second N-type high doping region 36 are used to form two ends of a capacitor. A first N-type high doping region 35 and two second N-type high doping regions 36 can be considered as a MOS device. Therefore, in the process of the MOS varactor of the invention, several MOS devices can be formed on the deep N well, and the gates of the MOS devices are coupled together to the first output terminal G while the sources and the drains of the MOS devices are coupled together to the second output terminal S/D.

FIG. 4 is a CV curve of the MOS varactor in FIG. 3. As shown in FIG. 4, the tuning range of the MOS varactor of the invention is obviously greatly increased. In this embodiment, the tuning range of the MOS varactor is about 6. In addition, in an ordinary condition (S/D terminal coupled to an AC ground), the MOS varactor can prevent noise interference due to deep N well isolation effect.

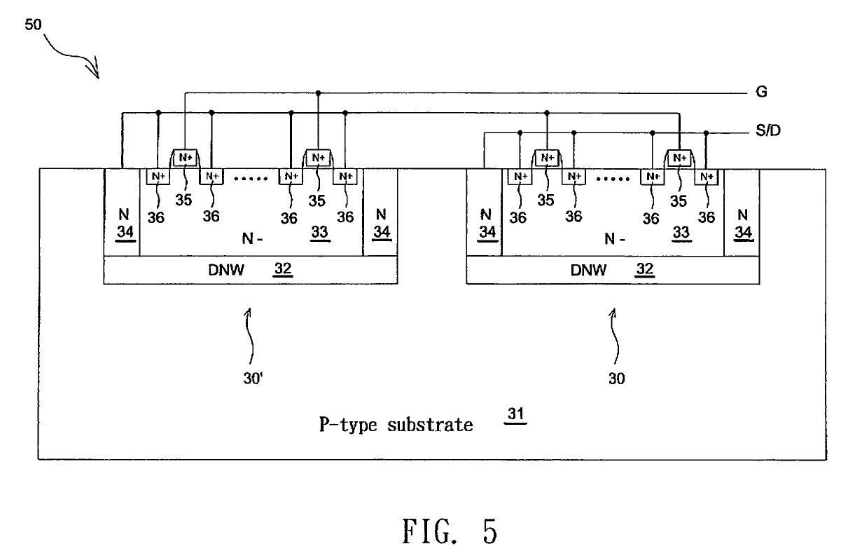

FIG. 5 shows the MOS varactor according to another embodiment of the invention. As shown in FIG. 5, two (or more than two) MOS varactors 30 and 30′ are coupled serially to provide a MOS varactor 50 having a relatively higher linearity. That is, the first output terminal G of the first MOS varactor 30 is coupled to the second output terminal S/D of the second MOS varactor 30′ while the first output terminal G of the second MOS varactor 30′ and the second output terminal S/D of the first MOS varactor 30 are respectively used as the first output terminal G and the second output terminal S/D of the MOS varactor 50.

The method of manufacturing the MOS varactor of the invention is described as the following by using the available process, for example, the TSMC 0.18 um RF process.

1. Form a deep N well (deep well) on the substrate;

2. Form the N well 34 on the deep N well;

3. Place at least a standard MOSFET device into the deep N well;

4. Cover by an optical mask to prevent the N-type doping region 33 and the channel of the MOSFET being ion implanted;

5. Form the first terminal of the varactor by using a metal layer to connect the deep N well and the S/D terminal;

6. Form the second terminal of the varactor by using a metal layer to connect the terminal G;

7. Serially couple two (or more than two) MOS varactors of the invention by a metal layer to provide a MOS varactor having large tuning range and linearity.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A metal oxide semiconductor (MOS) varactor, comprising:
a P-type substrate;
a deep N well, formed on the P-type substrate;
a first N-type doping region, formed on the deep N well;
an N well, formed on the deep N well and surrounding the first N-type doping region;
at least one second N-type doping region, formed on the first N-type doping region, and coupled together as a first terminal; and
at least one third N-type doping region, formed on the first N-type doping region, and coupled together as a second terminal.

2. The MOS varactor of claim 1, wherein the third N-type doping regions are coupled to the N well.

3. The MOS varactor of claim 1, wherein the N well is a N-type high doping region.

4. The MOS varactor of claim 1, wherein the first N-type doping region is formed by the neutralization of ions of the P-type substrate and the deep N well at the shallow layer.

5. The MOS varactor of claim 1, wherein the third N-type doping regions and the second N-type doping regions are configured in turn.

6. A metal oxide semiconductor (MOS) varactor having a first terminal and a second terminal, comprising:
a substrate;
a deep well, formed on the substrate; and
a first MOS device, formed on the deep well;
wherein a gate of the first MOS device is coupled to the first terminal, and a source and a drain of the first MOS device are coupled to the second terminal.

7. The MOS varactor of claim 6, wherein the deep well is coupled to the second terminal via a first well.

8. The MOS varactor of claim 6, further comprising at least one second MOS device, formed on the deep well, wherein the gates of the first and the second MOS devices are coupled, and the sources and the drains of the first and the second MOS devices are coupled.

9. The MOS varactor of claim 8, wherein the deep well is coupled to the second terminal via a first well.

10. The MOS varactor of claim 6, wherein the substrate is a P-type substrate and the deep well is a deep N well.

11. The MOS varactor of claim 6, wherein the first MOS device comprises:
a first doping region, formed on the deep well;
at least one second doping region, formed on the first doping region, and coupled together to the first terminal; and
at least one third doping region, formed on the first doping region, and coupled together to the second terminal.

12. The MOS varactor of claim 11, wherein the first, second, and third doping regions are a N-type doping region.

13. The MOS varactor of claim 6, further comprising: a well, formed on the deep well and surrounding the first MOS device.

14. The MOS varactor of claim 13, wherein the well is coupled to the second terminal.

15. The MOS varactor of claim 13, wherein the well is a N-type high doping region.

16. A method of manufacturing a metal oxide semiconductor (MOS) varactor which has a first terminal and a second terminal, the method comprising:
forming a deep well on a substrate;
forming a first MOS device on the deep well;
coupling a gate of the first MOS device to the first terminal; and
coupling a source and a drain of the first MOS device to the second terminal.

17. The method of claim 16, wherein the deep well is coupled to the second terminal via a first well.

18. The method of claim 16, further comprising:
covering the channel of the first MOS device with an optical mask to prevent ion-implanted.

19. The method of claim 16, further comprising:
forming at least one second MOS device on the deep well;
coupling a gate of the second MOS device to the first terminal; and
coupling a source and a drain of the second MOS device to the second terminal.
